(19) United States
(12) Patent Application Publication
(10) Pub. No.: US 2006/0204902 A1
(43) Pub. Date: Sep. 14, 2006

(54) Method for manufacturing organic electroluminescence display

(75) Inventors: Kyung Hee Choi, Seoul (KR); Seung Jun Yi, Seoul (KR)

Correspondence Address: BACON & THOMAS, PLLC, 625 SLATERS LANE, FOURTH FLOOR, ALEXANDRIA, VA, 22314, US

(73) Assignee: DAEWOO ELECTRONICS Corporation, Seoul (KR)

(21) Appl. No.: 11/431,589

(22) Filed: May 11, 2006

Related U.S. Application Data
(63) Continuation of application No. PCT/KR05/04283, filed on Dec. 14, 2005.

(30) Foreign Application Priority Data
Dec. 15, 2004 (KR) 10-2004-0106299

(51) Int. Cl. H01J 9/227

(52) U.S. Cl. 430/321; 430/330

(57) ABSTRACT

A method for manufacturing an organic electroluminescence display includes the steps of forming a plurality of strip-shaped first electrodes on a substrate, forming a positive photoresist layer on an entire surface of the substrate, patterning the positive photoresist layer to remain on a first area crossing the first electrodes and on a second area between the first electrodes, performing a first exposure process on a third area of the patterned positive photoresist layer, the third area being crossed the first electrodes, performing a first silylation process on the exposed positive photoresist layer, and performing an ashing process on the first to the third areas of the positive photoresist layer with an oxygen plasma.

This application is a Continuation Application of PCT International Application No. PCT/KR2005/004283 filed on Dec. 14, 2005, which designated the United States.

### FIELD OF THE INVENTION

The present invention relates to a method for manufacturing an organic electroluminescence (EL) display, capable of greatly reducing a product cost of an organic EL display and also preventing a discharge of an organic solvent or moisture remaining in an insulating film and a separate structure to pixels and a degradation of the pixels.

### BACKGROUND OF THE INVENTION

In general, an organic electroluminescence (hereinafter referred to as an EL) display is one of flat plate type displays. The organic EL display includes an anode layer and a cathode layer formed on a transparent substrate, and an organic light-emitting layer is interposed between the anode layer and the cathode layer. The organic EL display has very thin thickness and it is fabricated as a matrix pattern.

Such an organic EL display is driven at a low voltage not greater than 15V, and it exhibits advanced characteristics in terms of brightness, viewing angle, response time, power consumption, and so forth, compared to other types of displays, for example, a TFT-LCD. Besides, the organic EL display has a response time of about 1 μs, which is much faster than other displays, and, therefore, it is suitable for use in a next-generation multimedia display to which a function of implementing motion pictures is essential.

Fabrication of the organic EL display includes in general the steps of coating an insulating layer and a separator, both of which are made of an electrically insulating material, in order on a substrate on which an anode layer is formed and patterning an organic light-emitting layer through an overhang structure of the separator.

Here, the insulating layer is formed on the entire surface of the anode layer except on dot-shaped openings defining pixels, and the insulating layer serves to prevent a leakage of a current at an edge portion of the anode layer.

Moreover, the separator formed on the insulating layer is arranged in a predetermined interval such that it crosses the anode layer. Further, the separator is configured to have an overhang structure with a negative-profile, and it functions to separate the cathode layer between neighboring pixels.

Accordingly, both the insulating layer and the separator are necessary for a stable fabrication of the organic EL display.

For the reason, there have been proposed various methods for manufacturing an organic EL display by forming an insulating layer and a separator through a simplified process.

First of all, disclosed in U.S. Pat. No. 5,701,055 (hereinafter referred to Reference 1) is a manufacturing method for an organic EL display, in which an exposure process and a developing process are conducted for each of two layers of photoresist layer, to thereby form an insulating layer and a separator individually.

In the method disclosed in Reference 1, an anode layer made of, e.g., an indium tin oxide (ITO), is formed on a transparent substrate in the shape of parallel stripes. Then, an insulating layer formed of, e.g., a positive photoresist layer is coated on the substrate on which the anode layer is provided.

Thereafter, the insulating layer is patterned through a photolithography process including an exposure process and a developing process such that it remains only on areas between the anode stripes and also on areas crossing the anode stripes. As a result, the insulating layer is patterned such that it exists on the entire surface of the anode layer except on dot-shaped openings patterned on the anode layer. That is to say, the insulating layer is patterned to have a lattice structure. Here, the openings define pixels of the organic EL display.

Afterward, a negative photoresist layer or the like is coated on the insulator pattern, and a separator with a negative-profile is obtained by patterning the negative photoresist layer through a photolithography process including an exposure and a developing processes. In this regard, the separator is arranged on the insulator pattern formed between the dot-shaped openings to cross the anode stripes, are configured to maintain a predetermined internal therebetween. Further, the separators have an overhang structure with a negative-profile to allow a cathode layer, which is to be formed later, to prevent from occurring short-circuit due to the connection to neighboring pixels. That is to say, the separator is formed to maintain a negative-profile by using a characteristic of the negative photoresist layer. Therefore, a short circuit between cathode layers of neighboring pixels can be prevented.

After a hard baking process is performed to remove moisture or an organic solvent existing in the insulating layer and the separator, an organic light-emitting layer and a cathode layer are sequentially deposited on the entire surface of the resultant structure having the separators by using a metal mask. In this connection, when the organic light-emitting layer is deposited on the anode layer in the openings, there is a likelihood that the thickness of the organic light-emitting layer is reduced near the separator because of a shadow effect due to the separator, thus causing a short circuit between the cathode layer deposited on top of the organic light-emitting layer and the underneath anode layer. However, this problem is prevented by the presence of the insulating layer with a positive profile that is formed below the separator.

In accordance with the method disclosed in Reference 1 described so far, a reliable organic EL display can be fabricated by defining pixels and patterning an organic light-emitting layer and a cathode layer by using an insulating layer and a separator that are formed individually. In the conventional method in Reference 1, however, two layers of photoresist layers are used to form the insulating layer and the separator individually. Meanwhile, since the photolithography process needs to be performed two times for each photoresist layer, the manufacturing process for the organic EL display becomes complicated and manufacturing costs increases.

Moreover, even if the hard baking process is performed after the formation of the insulating layer and the separator, some of the moisture and the organic solvent remain in the insulating layer and the separator without being completely removed. Thus, when the organic EL display is driven, the moisture and the organic solvent may be discharged to a pixel by an outgassing and then degrade the pixel. Accordingly, defects such as dark spots or the like are made in the organic EL display, thereby deteriorating the reliability of the display and reducing a life time thereof.

Since the method described in Reference 1 has such problems as mentioned above, there has been a demand for a further advanced method for fabricating an organic EL display capable of achieving a simple fabricating process and a reduced product cost and also avoiding problems caused by moisture and an organic solvent outgassed from the insulating layer and the separator.

Korean Patent No. 408091 (Hereinafter referred to as Reference 2) discloses one of such methods.

The method described in Reference 2 involves forming an insulating layer and a negative-profile trench serving as a separator through patterning an image-reversal photoresist layer of a single layer by performing an exposure process two times, and also performing an exposure process one time and a developing process two times using a half tone mask. Detailed description of the method will be provided below.

As in the method described in Reference 1, an anode layer made of, e.g., an ITO is formed on a transparent substrate in the shape of a plurality of parallel stripes. Then, an image-reversal photoresist layer is coated on the transparent substrate on which the anode layer is provided. Thereafter, a first exposure process using a half tone mask and a developing process are performed, whereby the image-reversal photoresist layer is patterned such that it only remains areas between the anode stripes and areas crossing the anode stripes. Thus patterned photoresist layer becomes to exist on the entire surface of the anode layer except on dot-shaped openings. That is, the photoresist layer has a lattice structure, and the openings define pixels.

Meanwhile, in the patterning step using the half tone mask, the image-reversal photoresist layer between the anode stripes is firstly exposed through a half tone pattern of the half tone mask and becomes to have a thinner thickness than its other areas crossing the anode stripes.

Thereafter, the image-reversal photoresist layer crossing the anode stripes is secondarily exposed to light through a photo mask that shields the trench regions which is to serve as a separator. Then, an image-reversal baking process and a third exposure process (a flood exposure process) are performed to change the property of the image-reversal photoresist layer. Due to the characteristic of the image-reversal photoresist layer, during the image-reversal baking process, the portions of the photoresist layer secondarily exposed to light are cross-linked and still remain after a second developing process without being affected by the flood exposure process. Further, the image-reversal photoresist layer present in the trench regions, which is not exposed to light during the second exposure process, maintains its inherent property of the positive photoresist layer, and thus is removable during the second developing process which will be performed after the flood exposure process. In this regard, by exposing an upper partial portion of the image-reversal photoresist layer corresponding to an area of trenches under the control of a flood exposure dose, only the upper partial portion of the image-reversal photoresist layer can be removed later by a second developing process and thus, the trenches of a certain depth can be formed.

If the second developing process is conducted afterward, a negative-profile trench with an overhang structure is formed on the area of the photoresist layer crossing the anode stripes, wherein the trenches serve as a separator. Thereafter, the hard baking process is performed to remove the moisture and the organic solvent remaining in the photoresist layer where the trenches of a negative-profile are formed.

In accordance with the manufacturing method as described above, an insulating layer for defining pixels can be formed by using the image-reversal photoresist layer and, at the same time, a trench serving as a separator can be formed on the portions of the insulting layer crossing the anode stripes.

The subsequent processes for forming an organic light-emitting layer and a cathode layer are identical to those described in Reference 1, and therefore, detailed description thereof will be omitted.

In accordance with the manufacturing method disclosed in Reference 2, an insulating layer and a trench serving as a separator can be formed by using an image-reversal photoresist layer of a single layer, a half tone mask (a first photo mask) and a shield mask (a second photo mask) Therefore, the manufacturing method in Reference 2 is simpler than the method of Reference 1, and the usage of the photoresist layer is reduced compared to Reference 1, and so the product cost such as a cost of materials or the like can be partially reduced.

The method in Reference 2, however, also has disadvantages in that the product cost of the organic EL display remains high as a result of using the half tone mask or the phase shift mask of a high price. Furthermore, the design of the half tone mask is very difficult, and the manufacturing process is very difficult.

Moreover, Reference 2 has drawbacks in that some of the moisture and the organic solvent remain in the insulating layer and the photoresist layer forming trenches without being completely removed by the hard baking process. Thus, the moisture and the organic solvent may be discharged to a pixel unit by the outgassing and then degrade the pixel unit. Accordingly, defects such as dark spots or the like are made in the failed organic EL display, thereby deteriorating the reliability of the display and reducing a life time thereof.

Therefore, there has been a demand for still another method for manufacturing an organic EL display, while solving the above-mentioned problems. The Application of PCT/KR2004/002366 (Hereinafter referred to as Reference 3) filed by the inventors of the present invention provides a method capable of solving some of theses problems of the conventional methods. In the method disclosed in Reference 3, an insulating layer and a separator is formed by patterning an image-reversal photoresist layer of a single layer by way of performing an exposure process and a developing process three and two times, respectively, by means of using a general photo mask. Detailed description of this method will be provided hereinafter.

As similar as in the methods in Reference 1 and Reference 2, an anode layer made of, e.g., an ITO is formed on a transparent substrate in the shape of a plurality of parallel stripes. Then, an image-reversal photoresist layer is coated on the transparent substrate on which the anode layer is provided. Thereafter, a first exposure process using a general photo mask and a developing process are conducted, to thereby perform a patterning of the image-reversal photoresist layer such that the photoresist layer only remains between the anode layers and on certain areas crossing the anode layers.

Afterward, the image-reversal photoresist layer is subjected to a second exposure process through the use of a photo mask for defining a region on which a separator will be formed. Then, the image-reversal photoresist layer is undergone through an image-reversal baking process, through which the characteristic of the image-reversal photoresist layer is changed to insoluble property in base developing solution. Subsequently, a flood exposure process (a third exposure process) is conducted. Due to the characteristic of the image-reversal photoresist layer, during the image-reversal baking process, a portion of the photoresist layer secondarily exposed to light, where the separator will be formed, is cross-linked and is left even after a second developing process without being affected by the flood exposure. Further, the image-reversal photoresist layer unexposed to light during the second exposure process maintains the characteristic of the original positive photoresist layer, and thus is removable during the second developing process performed after the flood exposure process.

Further, during the flood exposure process, an exposure energy can be controlled such that the portion of the image-reversal photoresist layer, which is not exposed to the second exposure, is not completely removed by the second developing process but remains with a thickness thinner than that of the separator, to thereby be allowed to serve as an insulating layer for defining pixels.

Then, if the second developing process is performed, a portion of the photoresist layer exposed by the second exposure is left and thus a negative-profile separator with an overhang structure is obtained. Further, the portion of the photoresist layer unexposed by the second exposure are also left with its thickness reduced thinner than that of the separator by the flood exposure process at the time of the development, thus serving as an insulating layer dedicated to define pixels. Thereafter, the hard baking process is performed to remove the moisture or the organic solvent existing in the insulating layer and the separator.

Subsequent processes for forming an organic light-emitting layer and a cathode layer are identical to those described in Reference 1 or 2, so detailed description thereof will be omitted.

The above-described method disclosed in Reference 3 has a merit in that an insulating layer and a separator can be formed by using an image-reversal photoresist layer of a single layer without having to use a high-price half tone mask with a design feature difficult to be fabricated. Therefore, by employing the method in Reference 3, some of the problems of Reference 2 can be solved.

However, the method in Reference 3 still has drawbacks in that the product cost of the organic EL display increases due to the use of the image-reversal photoresist layer of a high price. Moreover, the moisture and the organic solvent remaining in the insulating layer and the separator, which are not completely removed by the hard baking process, make to degrade the pixels by the outgassing, thus deteriorating the reliability of the display and reducing a life time thereof.

### SUMMARY OF THE INVENTION

It is, therefore, an object of the present invention to provide a method for manufacturing an organic electroluminescence (EL) display, capable of greatly reducing a product cost by forming both an insulating time and a separator with the use of a positive or a negative photoresist layer of a single layer.

In accordance with one aspect of the present invention, there is provided a method for manufacturing an EL display, which includes the steps of: (a) forming a plurality of strip-shaped first electrodes on a substrate; (b) forming a positive photoresist layer on an entire surface of the substrate where the plurality of first electrodes are formed; (c) patterning the positive photoresist layer to remain a first area of the positive photoresist layer crossing the first electrodes and a second area of the positive photoresist layer between the first electrodes; (d) performing a first exposure process on a third area of the patterned positive photoresist layer, the third area being crossed the plurality of first electrodes; (e) performing a first silylation process on the positive photoresist layer exposed by the first exposure step (d); (f) performing an ashing process on the first to the third areas of the positive photoresist layer with an oxygen plasma; and (g) performing a hard baking process on the ashed result.

In accordance with another aspect of the present invention, there is provided a method for manufacturing an EL display method, which includes the steps of: (a) forming a plurality of strip-shaped first electrodes on a substrate; (b) forming a negative photoresist layer on an entire surface of the substrate where the plurality of first electrodes are formed; (c) performing a first exposure process on a first area of the negative photoresist layer crossing the first electrodes; (d) performing a first baking process on the exposed negative photoresist layer by the first exposure step (c); (e) developing a remainder of the negative photoresist layer unexposed by the first exposure step (c) to leave a designated thickness of the negative photoresist layer; (f) performing a second exposure process on areas of the negative photoresist layer excepting the second area crossing the first electrodes and the third area between the first electrodes; (g) performing a second baking process on the exposed negative photoresist layer by the second exposure step (f); (h) performing a third exposure process on the entire surface of the negative photoresist layer; (i) performing a first silylation process on the exposed negative photoresist layer by the third exposure step (h); (j) processing the entire surface of the negative photoresist layer with an oxygen plasma; and (k) performing a hard baking process on the ashed result.

### BRIEF DESCRIPTION OF THE DRAWINGS

The above and other objects and features of the present invention will become apparent from the following description of preferred embodiments, given in conjunction with the accompanying drawings, in which:

FIG. 1 is a schematic plan view of an organic electroluminescence (EL) display in accordance with the present invention;

FIGS. 2A to 2G show cross sectional views taken along a line A-A′ in FIG. 1 to illustrate a process for manufacturing an organic EL display in accordance with a first preferred embodiment of the present invention;

FIGS. 3A to 3G provide cross sectional views taken along a line B-B′ in FIG. 1 to illustrate the process for manufacturing an organic EL display in accordance with the first preferred embodiment of the present invention;

FIGS. 4A to 4I describe cross sectional views taken along a line A-A′ in FIG. 1 to illustrate a process for manufacturing an organic EL display in accordance with a second preferred embodiment of the present invention; and

FIGS. 5A to 5I present cross sectional views taken along a line B-B′ in FIG. 1 to illustrate the process for manufacturing an organic EL display in accordance with the second preferred embodiment of the present invention.

### DETAILED DESCRIPTION OF THE PREFERRED EMBODIMENTS

Hereinafter, preferred embodiments of the present invention will be described in detail with reference to the accompanying drawings.

In the drawings, thickness of various layers and regions therein are enlarged for the clear illustration thereof. Like reference numerals designate the same or corresponding parts in the various drawings.

Below, after briefly describing a structure of an organic electroluminescence (EL) display fabricated in accordance with the present invention, a method for manufacturing the organic EL display will be explained in detail in accordance with preferred embodiments of the present invention with reference to the accompanying drawings.

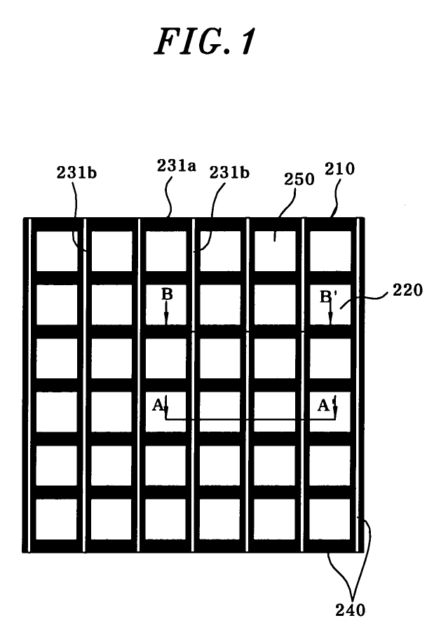

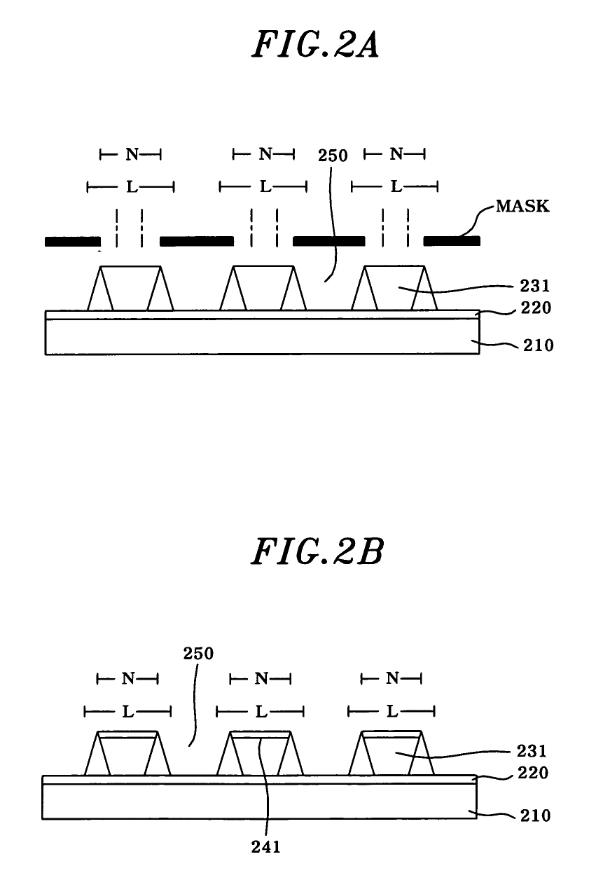

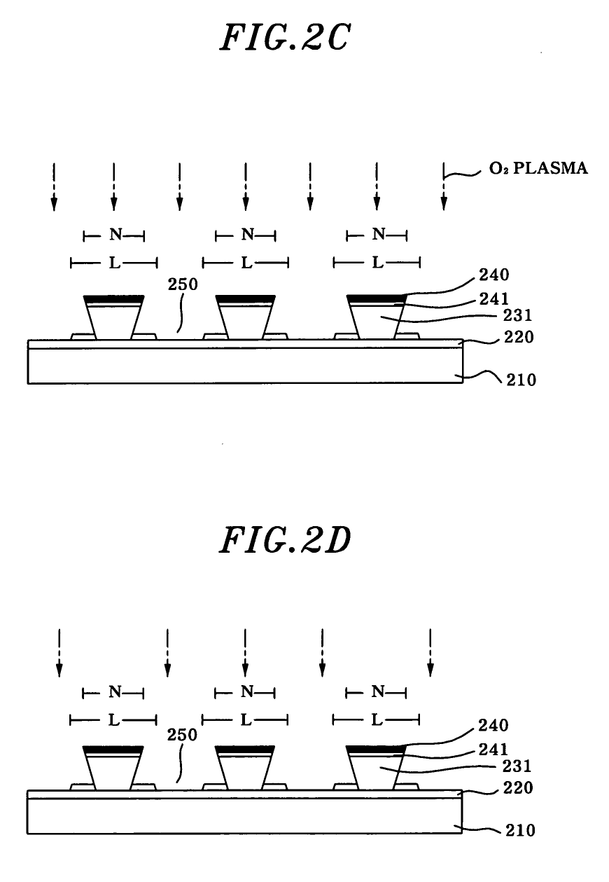

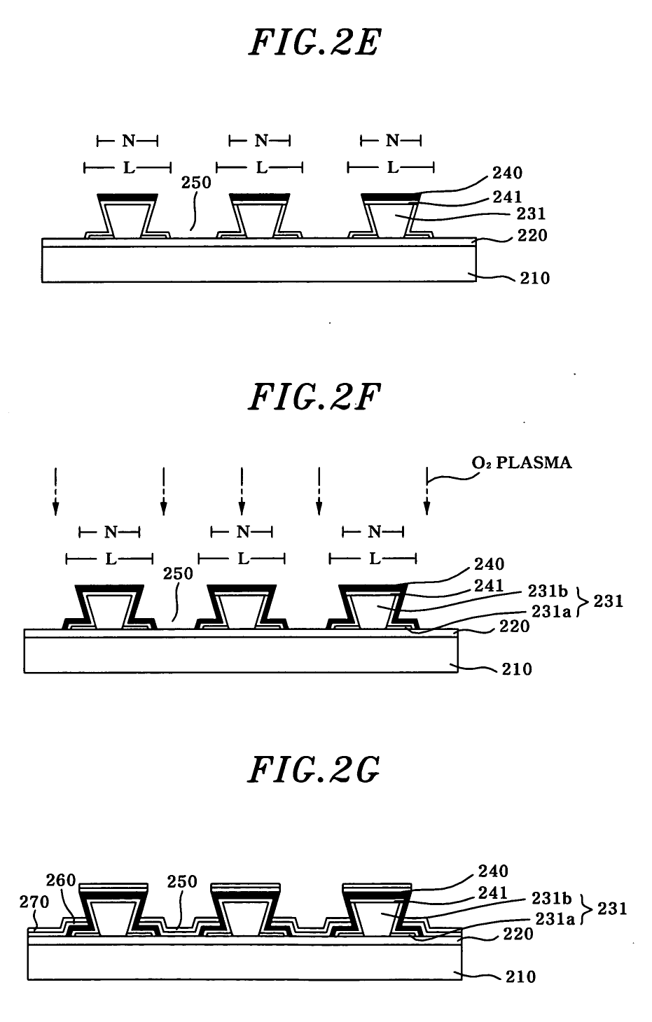

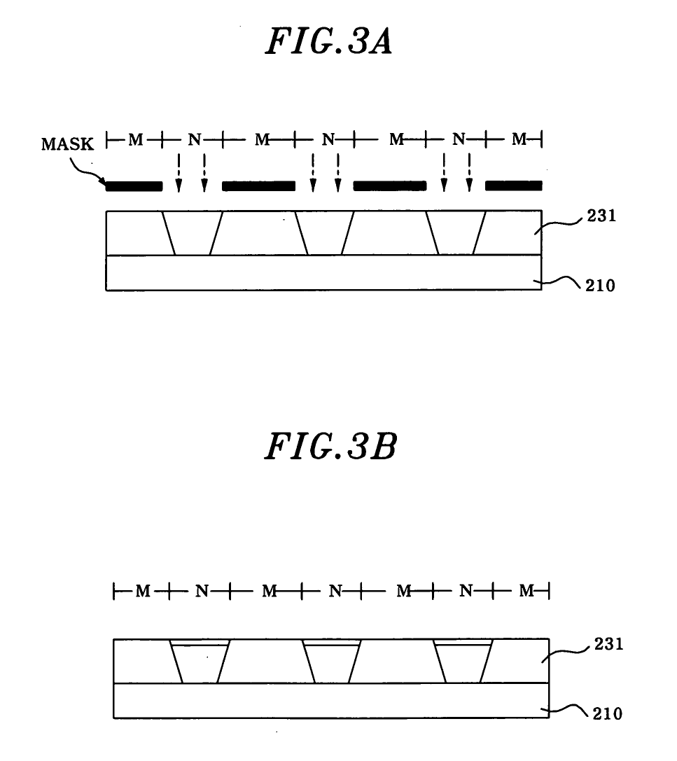

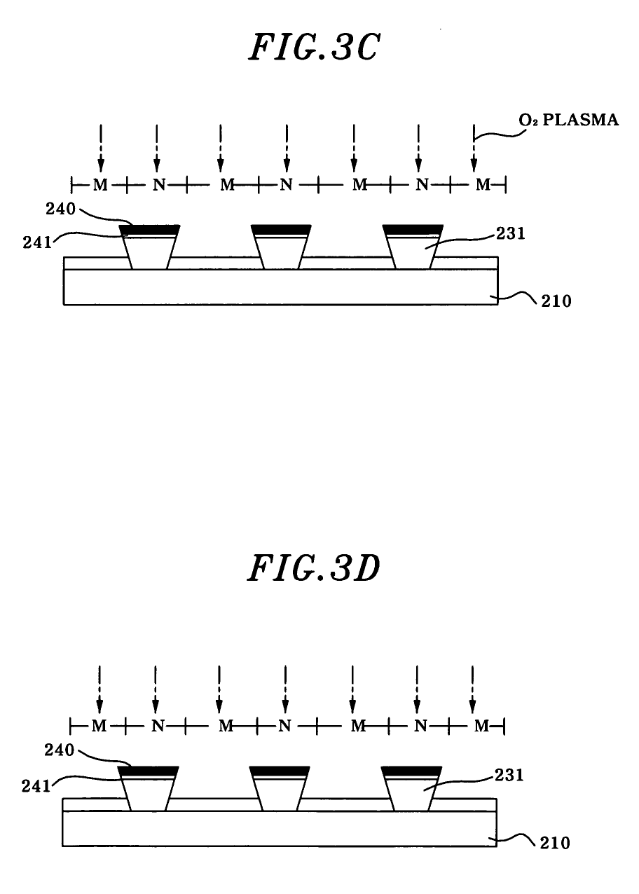

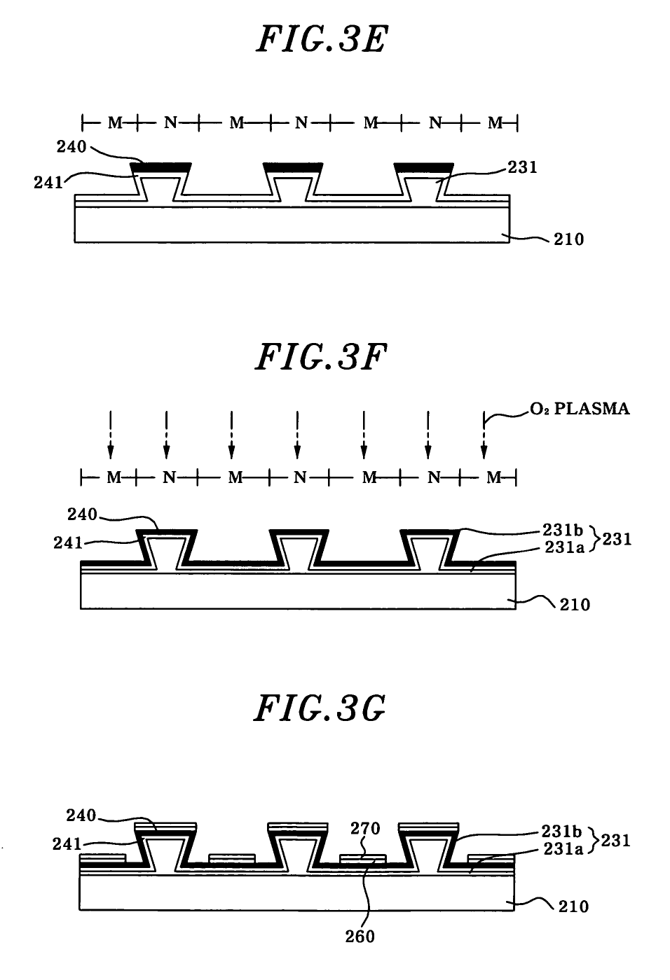

FIG. 1 shows an organic EL display fabricated in accordance with the present invention (herein, an organic luminescence layer and a second electrode are not shown for convenience); FIG. 2G shows a sectional view of the organic EL display fabricated in accordance with a first preferred embodiment of the present invention, which is taken along a line A-A′ of FIG. 1; and FIG. 3G provides a sectional view of the organic EL display fabricated in accordance with the first preferred embodiment of the present invention, which is taken along a line B-B′ of FIG. 1.

As illustrated in FIGS. 1, 2G and 3G, a plurality of first electrodes 220, which are made of indium tin oxide (ITO), indium-doped zinc oxide (IZO or IXO), or the like, is arranged on a transparent substrate 210 in the shape of stripes. An insulating layer 231a having a lattice pattern is formed on the transparent substrate 210 having the first electrodes 220 in an area between the neighboring first electrodes 220 and an area crossing with the first electrodes 220. Further, separators 231b for use in patterning an organic light-emitting layer 260 and second electrodes 270 are formed on the insulating layer 231a crossing the first electrodes 220. The insulating layer 231a of the lattice pattern defines openings 250 that expose pixel regions on the first electrodes 220. Each of the separators 231b serves to pattern the organic light-emitting layer and the second electrodes 270 in each pixel.

In the meantime, in the organic EL display fabricated in accordance with the present invention, a partial or an entire surface of the insulating layer 231a and the separators 231b is silylated, thus forming a silylated reactive film 241. Further, a hydrophobic silicon oxide film 240 of a certain thickness is formed on the silylated reactive film 241. In other words, the silylated reactive film 241 and the silicon oxide film 240 are formed on the insulating layer 231a and the separators 231b. By the help of the hydrophobic silicon oxide film 240, moisture can be prevented from penetrating or being adsorbed into the insulating layer 231a and the separators 231b, and also, the moisture or the organic solvent remaining in the insulating layer 231a and the separators 231b, which has not been completely removed, is hardly discharged during fabricating. Accordingly, it is possible to solve the drawbacks in which the pixels degraded by the moisture and the organic solvent during the driving of the organic EL display causes defect such as dark spots or the like. As a result, the reliability of the organic EL display is greatly enhanced.

Further, an organic light-emitting layer 260 and second electrodes 270 are sequentially formed on the first electrodes 220 of the openings 250 in order.

A method for fabricating the organic EL display with the above-described configuration will now be described.

FIG. 1 shows an organic EL display fabricated in accordance with the present invention (herein, an organic luminescence layer and a second electrode are not shown for convenience).

FIGS. 2A to 2F show cross sectional views taken along a line A-A′ in FIG. 1 to illustrate a process for manufacturing an organic EL display in accordance with a first preferred embodiment of the present invention; and FIGS. 3A to 3F provide cross sectional views taken along a line B-B′ in FIG. 1 to describe the process for manufacturing an organic EL display in accordance with the first preferred embodiment of the present invention.

In the manufacturing process of the organic EL display device in accordance with the first preferred embodiment, such a material for forming first electrodes as ITO, IZO (IXO) or the like is entirely deposited on the transparent substrate 210 made of transparent glass or plastic, wherein the thickness of the deposit ranges from about 1000 Å to 3000 Å. More specifically, the material for the first electrodes is deposited on the cleaned transparent substrate 210 by a sputtering method, and the surface resistance of the deposited material is set to be not greater than 10 Ω/cm². Also, by performing a photolithography process including an exposure and developing processes to a photoresist layer (not shown), the deposited material is patterned in the shape of stripes, thus obtaining first electrodes 220 as an anode layer.

Thereafter, a positive photoresist layer 231 is deposited on the entire surface of the transparent substrate 210 on which the plurality of first electrodes 220 is formed in the strip shapes. Any of positive photoresist layers that are commonly used in the manufacturing process of semiconductors or various types of displays, e.g., a polyimide-based positive photoresist film can be employed as the positive photoresist layer 231, where an ultraviolet lay may be utilized as an optical source. The following description will be provided for the case of utilizing the polyimide-based positive photoresist film as the positive photoresist layer. In such a case, the thickness of the positive photoresist layer 231 is preferably determined between 1 μm and 5 μm inclusive and, more preferably, between 3 μm and 5 μm inclusive.

After depositing the positive photoresist layer 231, a prebaking process is conducted at a temperature of 120° C. for a time period of about 120 seconds to dry the resultant structure. Thereafter, by performing a photolithography process including an exposure and a development, areas “L” which correspond to the portions of the positive photoresist layer 231 crossing the first electrodes 220 and areas “M” which correspond to the portions of the positive photoresist layer 231 between the first electrodes 220 are patterned. In this regard, the exposure process is carried out with exposure energy of 300 to 600 mJ/cm², and the development process is performed for about 60 seconds by using a base developing solution. As a result, the positive photoresist layer 231 is patterned as a lattice structure for defining openings 250 of each pixel. The aforementioned processes are identical to those of References 2 and 3 except that a positive photoresist layer is used instead of an image-reversal photoresist layer.

Thereafter, as can be seen from FIGS. 2A and 3A, a first exposure process is performed on third areas “N” which correspond to the portions of the patterned photoresist layer 231 crossing the first electrodes 220. The first exposure process generates acid in the positive photoresist layer 231 on the third areas “N” for defining areas where separators of an overhand structure will be formed, thereby enabling a first silylation process to be performed later. The first exposure process is performed with an exposure energy of 300 to 600 mJ/cm², as same as the exposure process for patterning the positive photoresist layer 231 as a lattice structure. As a result of the first exposure process, as can be seen from a following Reaction Scheme 1, PAC (Photoactive compound) contained in the positive photoresist layer 231 on the exposed third areas “N” changes into a compound having an acid functional group, i.e., —COOH. Accordingly, the acid is generated and, thus, a silylation reaction can be performed later.

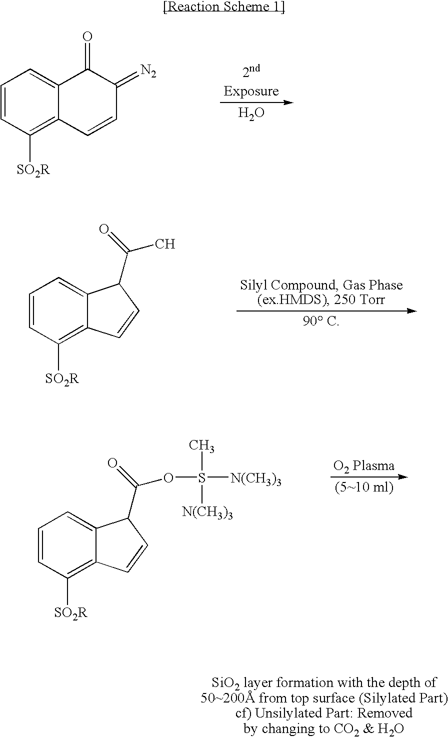

Meanwhile, the first exposure process can be performed by using a photo mask having as a light-transmitting area the third areas “N” whose width is smaller than an upper width of the first areas “L” corresponding to the patterned positive photoresist layers 231. The photo mask is preferably aligned such that centers of the third areas “N” serving as a light-transmitting area coincides with those of the patterned positive photoresist layers 231 on the first areas “L”.

In this regard, the third areas “N” define areas for separators of an overhang structure, and the first areas “L” define areas for an insulating layer having a positive profile. If the third areas “N” have a width larger than an upper width of the first areas “L” corresponding to the patterned positive photoresist layers 231, the insulating layer having a positive profile under the separators is formed considerably narrow or inappropriately formed. Moreover, in case the centers of the third areas “N” do not coincide with those of the third areas “L” corresponding to the patterned positive photoresist layers 231, the insulating layer under the separators may be asymmetrically formed.

After the first exposure process is carried out, as can be seen from FIGS. 2B and 3B, a first silylation process is performed on the first-exposed positive photoresist layers 231. The first silylation process can be carried out by reacting surfaces of the first-exposed positive photoresist layers with one or more silyl compounds selected from a group including trimethylsilyldiethylamine, N,N-dimethylaminotrimethylsilane, 1,1,3,3-tetramethyldisilane, dimethylsilyldimethylamine, dimethylsilyldiethylamine, hexamethylcyclotrisilazine and bis(N,N-dimethylamino)methylsilane. Further, during the reaction with the silyl compound, it is preferable to set a reaction temperature to be 90° C. and a reaction pressure to be about 250 Torr. Furthermore, the silyl compound in a gas or a liquid state is applied to the first-exposed positive photoresist layers 231.

As a result of the first silylation process, as can be seen from the Reaction Scheme1, the compound having an acid functional group reacts with the silyl compound on the surfaces of the first-exposed positive photoresist layers 231 corresponding to the third areas “N”, thereby silylating the acid functional group from —OH to —Osilyl. Consequently, the silylation reactive films 241 having a thickness of 3000 Å or less are formed on upper surfaces of the first-exposed positive photoresist layers 231. On the other hand, positive photoresist layers on the remaining areas, which are not exposed to the first exposure, do not react with the silyl compound due to the unchanged PAC contained therein and thus maintain the original state where the silylation reactive film 241 is not formed thereon. Meanwhile, after performing the first silylation process, as can be seen from FIGS. 2C and 3C, the positive photoresist layers corresponding to the first to the third areas “L” to “N” are ashed by using an oxygen plasma. In this regard, it is preferable to apply the oxygen plasma of about 5 to 10 ml.

Once the oxygen plasma ashing process is performed, a silyl group reacts with the oxygen plasma on the silylation reactive films 241 formed on the upper surface of the third areas “N”, thereby forming the silicon oxide films 240 having a thickness of, e.g., about 50 Å to 200 Å, on silylation reactive films 241. However, the silylation reactive films 241 are not formed on the positive photoresist layers 231 on the first and the second areas “L” and “M” except the third areas “N”, so that the silicon oxide films 240 cannot be formed. Instead, a certain thickness of the positive photoresist layers 231 on those areas is dry-etched by the oxygen plasma ashing process. In this regard, a certain thickness of the positive photoresist layers 231 corresponding to those areas permits to be left without being completely removed by controlling conditions of the oxygen plasma for the ashing process.

If the oxygen plasma ashing process is completed, as can be seen from FIGS. 2C and 3C, the third areas “N” remaining on the positive photoresist layers 231 crossing the first electrodes 220 are configured as separators of an overhang structure. And the positive photoresist layers 231 remaining with a low thickness in the first areas “L” crossing the first electrodes 220 and the second areas “M” between the first electrodes 220 are configured as lattice patterned insulating layers for defining the openings 250 for pixels. Moreover, the hydrophobic silicon oxide films 240 and the silylation reactive films 241 are formed on the upper surfaces of the third areas “N” of the positive photoresist layers 231, so that the organic solvent or the moisture remaining in the positive photoresist layers 231 can be prevented from being discharged to the pixel by an outgassing during the driving of the organic EL display.

In the meantime, after the oxygen plasma ashing process is performed, a general hard baking process is carried out to remove most of the moisture or the organic solvent remaining in the positive photoresist layers 231 (through the surfaces of the positive photoresist layers 231 where the silicon oxide films 240 and the like are not formed). At this time, even if the hard baking process is performed, the organic solvent and the moisture may remain in the positive photoresist layers 231 without being completely removed. As described above, however, in the organic EL display in accordance with this preferred embodiment, since the hydrophobic silicon oxide film 240 or the like are formed on the positive photoresist layers 231, the moisture can be prevented from penetrating or being adsorbed thereinto during the fabricating process and, also, the incompletely removed moisture or organic solvent remaining in the positive photoresist layers 231 can be prevented from being discharged to the pixel unit.

Meanwhile, after the hard baking process is carried out, a second exposure process is performed on entire surfaces of the positive photoresist layers 231, as shown in FIGS. 2D and 3D. As same as the first exposure process, the second exposure process is performed with exposure energy of about 300 to 600 mJ/cm², to thereby enable a second silylation process later by way of generating acid in the positive photoresist layers 231 overall. As a result of the second exposure process (a flood exposure process), as can be seen from the Reaction Scheme 1 and the first exposure process, the PAC changes into a compound having an acid functional group, i.e., —COOH, in the positive photoresist layers 231 on every area. Accordingly, the acid is generated and, thus, a silylation reaction can be performed later.

Next, as illustrated in FIGS. 2E and 3E, a second silylation process is performed on the second-exposed positive photoresist layers 231. Since a specific procedure of the second silylation process is mostly same as that of the first silylation process, a detailed description thereof will be omitted.

Once the first silylation process is carried out, as same as in the first silylation process, the compound having an acid functional group in the positive photoresist layers 231 reacts with the silyl compound except the upper surfaces of the positive photoresist layers 231 having thereon the silicon oxide films 240 and the silylation reactive film 241, thereby silylating the acid functional group from —OH to —Osilyl. Consequently, the silylation reactive films 241 having a thickness of about 3000 Å or less are formed on the entire surfaces except the upper surfaces of the positive photoresist layer 231.

Meanwhile, after the second silylation process is performed, as can be seen from FIGS. 2F and 3F, the surfaces of the second-silylated positive photoresist layers 231 are processed by using an oxygen plasma. In this regard, it is preferable to apply the oxygen plasma of about 5 to 10 ml.

Once the oxygen plasma ashing process is performed, a silylation of the silylation reactive films 241 reacts with the oxygen plasma on every surface except the upper surfaces of the positive photoresist layers 231 having thereon the silicon oxide films 240, thereby forming the silicon oxide films 240 having a thickness of about 50 Å to 200 Å, for example, on the silylation reactive films 241.

Consequently, if the second silylation process is completed, the positive photoresist layers 231 composed of the insulating layers 231a having a positive profile and the separators 231b of an overhang structure are finally completed. Especially, in this embodiment, since the hydrophobic silicon oxide films 240 are formed on the entire surfaces of the insulating layers 231a and the separators 231b, the insulating layers 231a and the separators 231b are formed in an integrated structure.

Thereafter, as shown in FIGS. 2G and 3G, an organic light-emitting layer 260 and a second electrode 270 serving as a cathode layer are formed on the first electrodes 220 on the transparent substrate where the insulating layers 231a and the separators 231b are formed, thereby manufacturing the organic EL display.

In other words, the method for manufacturing an organic EL display in accordance with the first preferred embodiment can greatly reduce a product cost of the organic EL display by simultaneously forming the insulating layers 231a having a positive profile and the separators 231b of an overhang structure with the use of a positive photoresist layer of a single layer instead of a image-reversal photoresist layer of a high price. Further, by forming the hydrophobic silicon oxide films 240 or the like on the surfaces of the insulating layers 231a and the separators 231b, it is possible to prevent moisture or an organic solvent remaining in the insulating layers 231a and the separators 231b from being discharged to an outside of the insulating layers 231a and the separators 231b, i.e., to the pixel.

Furthermore, in accordance with this embodiment, by forming the hydrophobic silicon oxide films 240, it is possible to prevent the insulating layers 231a and the separators 231b from being contaminated by moisture infiltrated or adsorbed from the outside during the manufacturing process of the organic EL display.

Hereinafter, a method for manufacturing an organic EL display in accordance with a second preferred embodiment will be described.

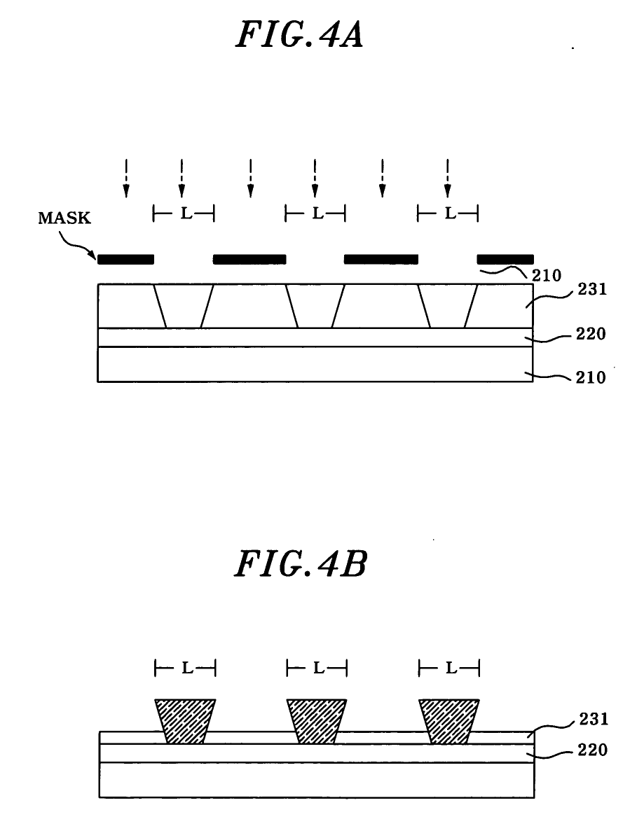

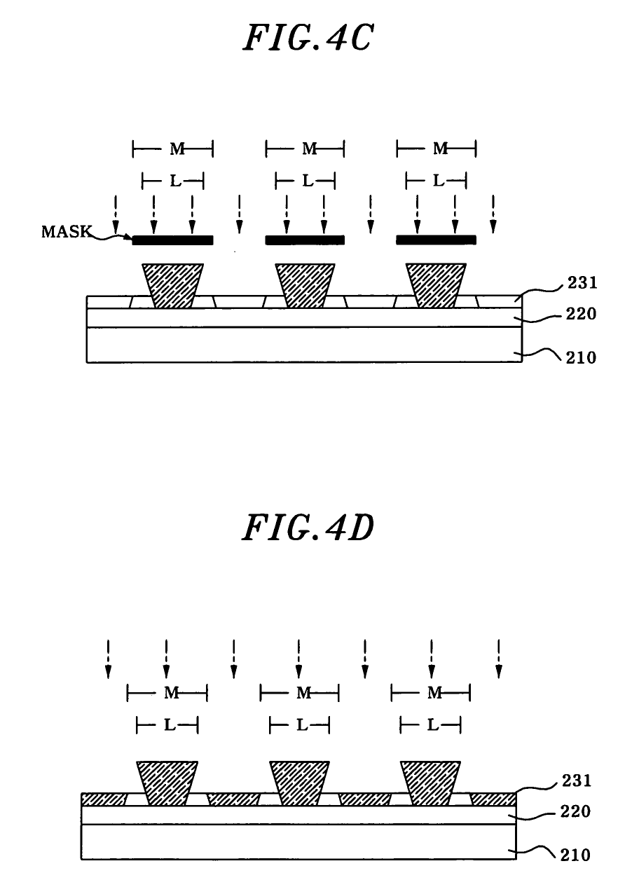

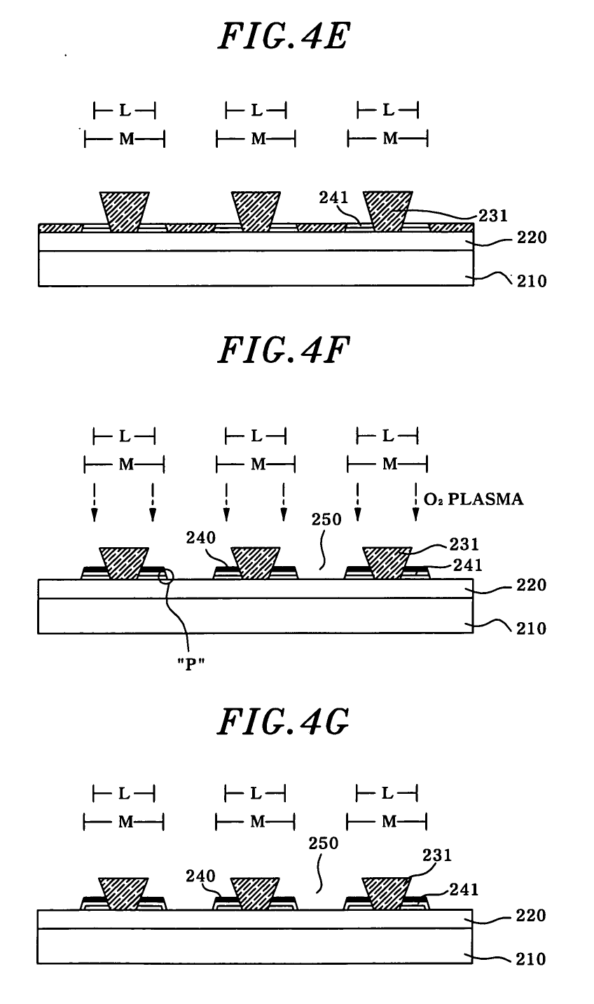

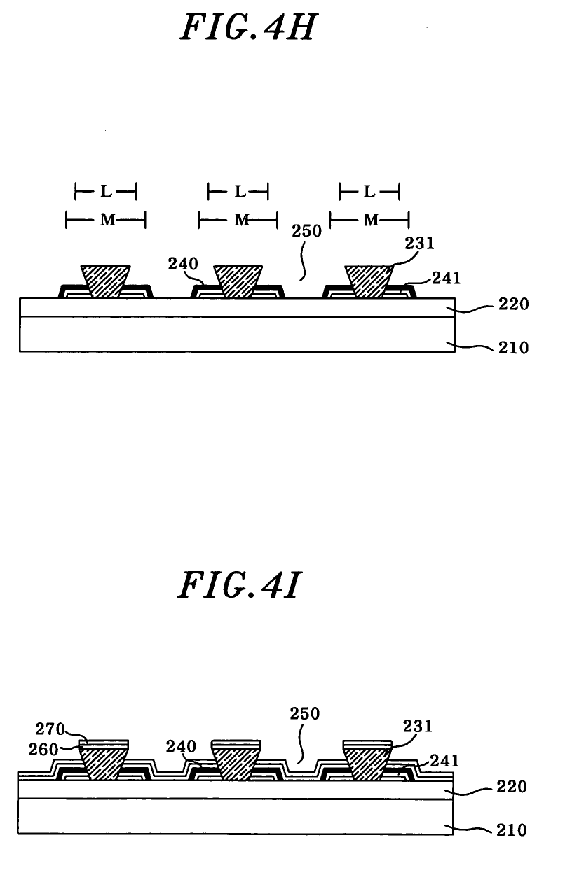

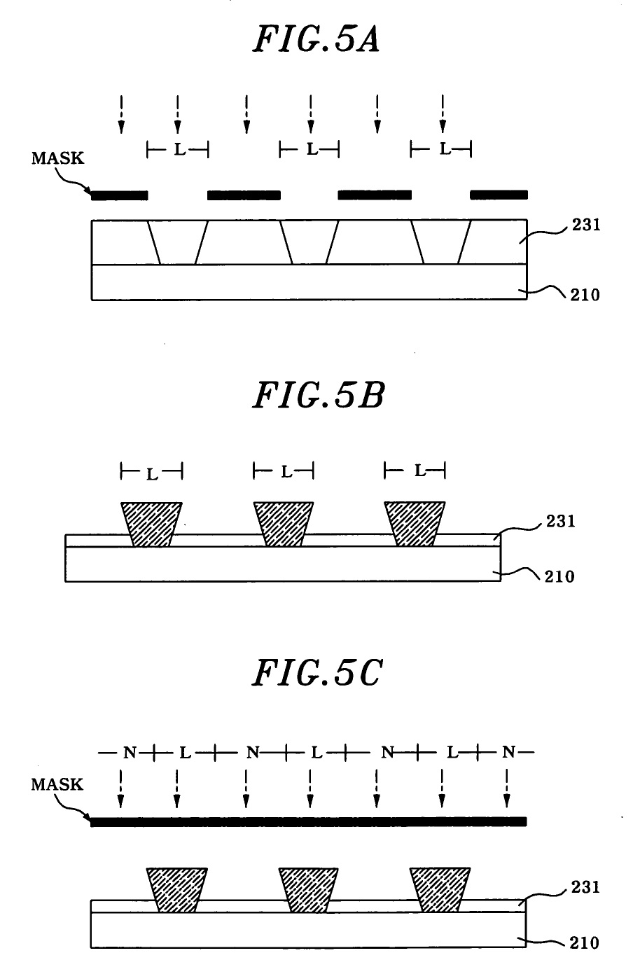

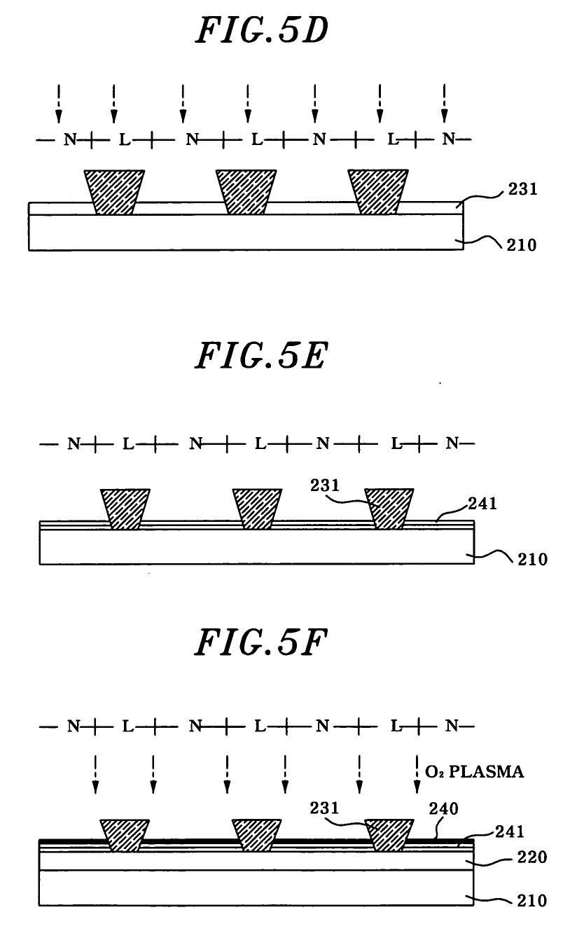

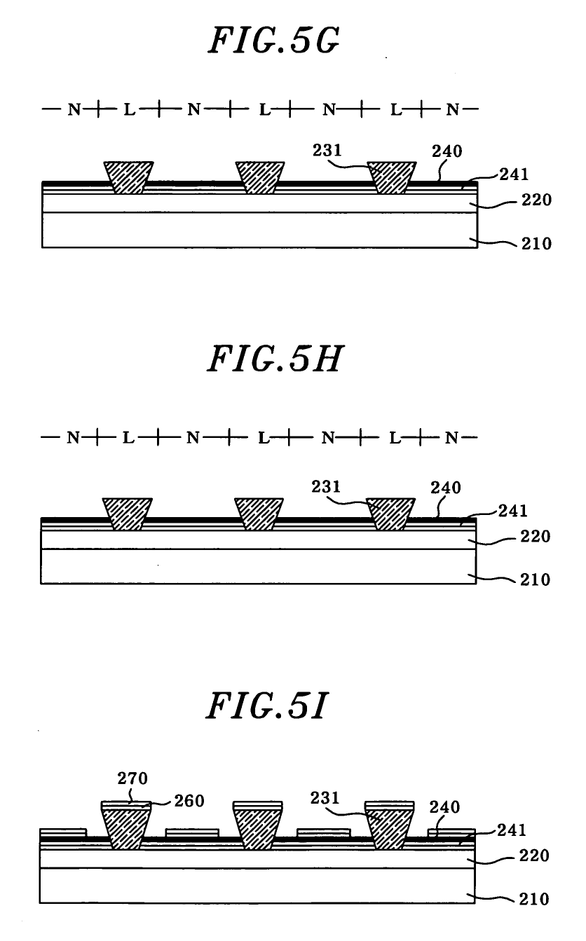

FIGS. 4A to 4G describe cross sectional views taken along a line A-A′ in FIG. 1 to illustrate a process for manufacturing an organic EL display in accordance with a second preferred embodiment of the present invention; and FIGS. 5A and 5B present cross sectional views taken along a line B-B′ in FIG. 1 to describe the process for manufacturing an organic EL display in accordance with the second preferred embodiment of the present invention.

In manufacturing the organic EL display in accordance with the second preferred embodiment, first of all, a plurality of strip-shaped first electrodes 220 are formed on a transparent substrate 210, and a negative photoresist layer 231 is deposited on an entire surface of the transparent substrate 210 having the first electrodes 220 formed thereon. Since the above described processes for the second preferred embodiment are identical to those of the first preferred embodiment except that the negative photoresist layer is used instead of the positive photoresist layer, a detailed description thereof will be omitted.

In the meantime, as for the negative photoresist layer 231, a general negative photoresist layer 231 for use in manufacturing semiconductor devices and various displays can be used. Further, it is preferable to use a Novolak negative photoresist layer and a UV light source as optical source (hereinafter, a composition employing the Novolak negative photoresist film will be described). A thickness of the negative photoresist layer 231 preferably ranges from 2 μm to 6 μm and, more preferably, from 4 μm to 6 μm.

After the negative photoresist layer 231 is coated, a prebaking process is performed at 110° C. for about 90 seconds to thereby dry the resultant obtained by coating the negative photoresist layer 231. Next, as shown in FIGS. 4A and 5A, a first exposure process is performed on first areas “L” corresponding to the portions of the negative photoresist layer 231 crossing the first electrodes. The first exposure process for patterning separators to be configured to have an overhang structure is carried out with an exposure energy of about 100 to 200 mJ/cm², thereby exposing the entire negative photoresist layer 231 where the separators will be formed.

As a result of the first exposure process, the acid is generated in the first-exposed areas on the negative photoresist layers 231, so that a cross-linking reaction can take place along with the baking process. After the first exposure process is completed, a first baking process is performed on the first-exposed negative photoresist layers 231. The first baking process can be carried out based on general baking processes for cross-linking the Novolak negative photoresist layer.

Once the first baking process is performed, the first-exposed negative photoresist layers 231, i.e., the first areas “L” of the negative photoresist layers 231 crossing the first electrodes, are cross-linked. On the other hand, the acid is not generated in the negative photoresist layers 231 on areas that are not exposed to the first exposure. Accordingly, the negative photoresist layers 231 maintain the original state and thus can be removed by a developing solution.

Next, if a developing process is performed by using a developing solution, as can be seen from FIGS. 4B and 5B, the cross-linked negative photoresist layers 231 corresponding to the areas that are not exposed to the first exposure, i.e., the areas other than the first areas “L”, are removed by the development. In this regard, if the developing process is performed for about 20 to 40 seconds while controlling developing process conditions, the unexposed areas on the negative photoresist layers 231 are not completely removed while leaving a certain thickness of the negative photoresist layers. The remaining negative photoresist layers 231 of the certain thickness include the negative photoresist layers 231 to be configured as insulating layers having a positive profile.

Consequently, if the developing process is completed, the separators of an overhang structure are patterned and, also, the remainder of the negative photoresist layers 231 is formed has a low thickness.

After the developing process is performed, as can be seen from FIGS. 4C and 5C, a second exposure process is performed on the negative photoresist layers 231 corresponding to areas other than the second areas “M” crossing the first electrodes and the third areas “N” between the first electrodes. In this regard, the second and the third areas “M” and “N” define areas where lattice patterned insulating layers for defining openings of each pixel will be formed. Therefore, during the second exposure process, the areas on the negative photoresist layers 231, where the openings of each pixel will be formed, are exposed. The second exposure process is preferably carried out with an exposure energy of 50 to 100 mJ/cm².

As a result of the second exposure process, the acid is generated in the second-exposed areas of the negative photoresist layers 231, so that the cross-linking reaction can take place along with a second baking process to be performed later. Meanwhile, the unexposed areas, i.e., the second and the third areas “M” and “N” of the negative photoresist layers 231 do not change. Thus, even if the second baking process is performed later, the cross-linking reaction does not take place. However, among the unexposed areas, the first areas “L” of the negative photoresist layers 231 crossing the first electrodes maintain the cross-linked state obtained by the first exposure process and the first baking process.

In the meantime, the second exposure process can be performed by using a lattice patterned photo mask having as shield areas the second areas “M” whose width is larger than that of the first areas “L” and the third areas “N”. Further, it is preferable to align the photo mask such that the centers of the second areas “M” shaded by the photo mask can coincide with those of the negative photoresist layers on the first areas “L”.

Here, the first areas “L” define areas for separators of an overhang structure, and the second areas “M” define areas for insulating layers having a positive profile. If the first areas “L” have a larger width than that of the second areas “M”, the insulating layers having a positive profile under the separators are formed considerably narrow or inappropriately formed. Moreover, in case the centers of the second areas “M” do not coincide with those of the first areas “L” of the negative positive photoresist layers 231, the insulating layers under the separators may be asymmetrically formed.

After the second exposure process is carried out, the second baking process is performed on the second-exposed negative photoresist layers 231. As same as the first baking process, the second baking process can be carried out based on general baking processes for cross-linking the Novolak negative photoresist layer.

Once the second baking process is performed, the second-exposed negative photoresist layers 231, i.e., the areas of the negative photoresist layers 231 for the openings of each pixel other than the second and the third areas “M” and “N”, are cross-linked. Thus, a silyl compound can be prevented from penetrating thereinto during a first silylation process to be performed later. On the contrary, the negative photoresist layers 231 on the second and the third areas “M” and “N” that are not exposed to the second exposure are cross-linked regardless of the baking process, thereby maintaining the original state thereof. However, as described above, the first areas “L” of the negative photoresist layers 231 maintain the cross-linked state obtained by the first exposure process and the first baking process. Therefore, the silyl compound can be prevented from penetrating thereinto during the first silylation process or the like regardless of the second exposure process and the second baking process.

Meanwhile, after the second baking process is completed, as shown in FIGS. 4D and 5D, a third exposure process is performed on entire surfaces of the negative photoresist layers 231. As same as the second exposure process, the third exposure process for carrying out the first silylation process later is performed with exposure energy of about 50 to 100 mJ/cm².

As a result of the third exposure process (flood exposure process), in the second and the third areas “M” and “N”, the acid generated by the exposure reacts in the negative photoresist layers 231 remaining with a certain low thickness. Accordingly, a Novolak main polymer changes into a polymer having a hydroxide functional group, e.g., —OH, thereby enabling the silylation reaction to take place later. On the contrary, the second-exposed areas of the negative photoresist layers 231 (i.e., the areas of the negative photoresist layers 231 for the openings of each pixel except the second and the third areas “M” and “N”) and the separator-shaped negative photoresist layers 231 remaining in the first areas “L” are strongly cross-linked state by the first and the second baking process. Accordingly, even if the third exposure process (flood exposure process) is carried out, the acid is hardly generated therein, so that the negative photoresist layers 231 can maintain the cross-linked state. After the third exposure process is completed, as can be seen from FIGS. 4E and 5E, the first silylation process is performed on the third-exposed negative photoresist layers 231. The first silylation process can be carried out by reacting surfaces of the third-exposed negative photoresist layers with one or more silyl compounds selected from a group including trimethylsilyldiethylamine, N,N-dimethylaminotrimethylsilane, 1,1,3,3-tetramethyldisilane, dimethylsilyldimethylamine, dimethylsilyldiethylamine, hexamethylcyclotrisilazine and bis (N,N-dimethylamino)methylsilane. Further, during the reaction with the silyl compound, it is preferable to set a reaction temperature to be 90° C. and a reaction pressure to be about 250 Torr. Furthermore, the silyl compound in a gas or a liquid state is applied to the third-exposed positive photoresist layers 231.

As a result of the first silylation process, the polymer having the hydroxide functional group, i.e., —OH, reacts with the silyl compound on the second and the third areas “M” and “N” of the surfaces of the positive photoresist layers 231, thereby silylating the functional group from —OH to —Osilyl. Consequently, silylation reactive films 241 having a thickness of 3000 Å or less are formed on upper surfaces of the second and the third areas “M” and “N” of the negative photoresist layers 231. On the other hand, since the remaining areas of the negative photoresist layers 231 are cross-linked by the first and the second baking process, the silyl compound cannot infiltrate thereinto due to the cross-linked structure. Thus, the silylation process does not take place on their surfaces and, accordingly, the negative photoresist layers 231 maintain its original state where the silylation reactive films 241 are not formed thereon.

Meanwhile, after the first silylation process is performed, as can be seen from FIGS. 4F and 5F, the entire surfaces of the negative photoresist layers 231 are ashed by using an oxygen plasma. In this regard, it is preferable to apply the oxygen plasma of about 5 to 10 ml.

Once the oxygen plasma ashing process is performed, a silyl group reacts with the oxygen plasma on the silylation reactive films 241 formed by the first silylation process, thereby forming the silicon oxide films 240 having a thickness of about 50 Å to 200 Å, for example, on the silylation reactive films 241. However, the silylation reactive films 241 are not formed on the areas for the openings of each pixel other than the second and the third areas “M” and “N” and on the first areas “A” of the negative photoresist layers 231 remaining in a separator shape, so that the formation of the silicon oxide films 240 is prohibited. Instead, those areas of the negative photoresist layers 231 are dry-etched by the oxygen plasma ashing process. As a result, the areas of the negative photoresist layers 231 for the openings of each pixel other than the second and the third areas “M” and “N” are completely removed by the dry-etching process. Further, the dry-etching process removes a certain thickness of the separator-shaped negative photoresist layers 231 remaining in the first areas “L” (e.g., the removed thickness of the negative photoresist layers 231 in the areas for the openings of each pixel), thereby reducing a height thereof.

Once the oxygen plasma ashing process is completed, as can be seen from FIGS. 4F and 5F, the negative photoresist layers 231 remaining in the first areas “L” crossing the first electrodes 220 are configured as separators of an overhang structure, and the positive photoresist layers 231 remaining with a low thickness in the second areas “M” crossing the first electrodes 220 and the third areas “N” between the first electrodes 220 are configured as lattice patterned insulating layers for defining the openings 250 of a pixel forming area. Moreover, the hydrophobic silicon oxide films 240 and the silylation reactive films 241 are formed on the surfaces of the negative photoresist layers 231 except end portions (portions “P” in FIG. 4F) of the second areas “M” in the negative photoresist layers 231 on the second and the third areas “M” and “N”, so that the organic solvent or the moisture remaining in the positive photoresist layers 231 can be prevented from being discharged to the pixel by an outgassing during the driving of the organic EL display.

In the meantime, after the oxygen plasma ashing process is performed, a general hard baking process is carried out to remove most of the moisture or the organic solvent remaining in the positive photoresist layers 231 (through the surfaces of the positive photoresist layers 231 where the hydrophobic silicon oxide films 240 and the silylation reactive films 241 are not formed). In this regard, even if the hard baking process is performed, the organic solvent and the moisture may remain in the positive photoresist layers 231 without being completely removed. However, as described above, in the organic EL display in accordance with this preferred embodiment, the hydrophobic silicon oxide films 240 or the like are formed on the positive photoresist layers 231; and, therefore, the moisture or the organic solvent remaining in the negative photoresist layers 231 can be prevented from being discharged to the pixel unit.

Meanwhile, after the hard baking process is carried out, a fourth exposure process is performed on entire surfaces of the positive photoresist layers 231. As same as the third exposure process or the like, the fourth exposure process is performed with an exposure energy of about 50 to 100 mJ/cm² to thereby perform a second silylation process later on the surfaces of the end portions (portions “P” in FIG. 4f) of the negative photoresist layers 231 on the second areas “M” by additionally generating acid in the positive photoresist layers 231 in the second and the third areas “M” and “N”.

As a result of the fourth exposure process (flood exposure process), as same as the result of the third exposure process, the main polymer changes into a polymer having a hydroxide functional group, i.e., —OH, in the negative photoresist layers 231 on the second and the third areas “M” and “N”, which enables a silylation reaction to take place later. In the meantime, the negative photoresist layers 231 remaining in the first areas crossing the first electrodes 220 are strongly cross-linked by the first and the second baking process. Thus, even if the fourth exposure process (the flood exposure process) is carried out, since the acid is hardly generated therein, the cross-linked state can be maintained.

Next, as can be seen from FIGS. 4G and 5G, a second silylation process is performed on the fourth-exposed negative photoresist layers 231. Since a specific procedure of the second silylation process is mostly same as that of the first silylation process, a detailed description thereof will be omitted.

Once the second silylation process is carried out, as same as in the first silylation process, the polymer having a hydroxide functional group in the negative photoresist layers 231 reacts with the silyl compound on the surfaces of the end portions of the second areas “M” of the negative photoresist layers 231, except the portions where the hydrophobic silicon oxide films 240 are formed and the cross-linked portions. Consequently, the hydroxide functional group is silylated from —OH to —Osilyl, thereby forming the silylation reactive films 241 having a thickness of about 3000 Å or less on the surfaces of the end portions of the second areas “M” of the negative photoresist layers 231.

Meanwhile, after the second silylation process is performed, as can be seen from FIGS. 4H and 5H, the surfaces of the second-silylated negative photoresist layers 231 are processed by using an oxygen plasma. It is preferable to apply the oxygen plasma of about 5 to 10 ml.

Once the oxygen plasma ashing process is performed, a silyl group of the silylation reactive films 241 reacts with the oxygen plasma on the surfaces of the negative photoresist layers 231, except the portions where the silicon oxide films 240 are formed and the cross-linked portions, i.e., on the surfaces of the end portions (portions “a”) of the second areas “M” of the negative photoresist layers 231, thereby forming the silicon oxide films 240 having a thickness of about 50 Å to 200 Å, for example, on the silylation reactive films 241.

Consequently, once the second silylation process is completed, as shown in FIGS. 4H and 5H, the negative photoresist layers 231 composed of the insulating layers 231a having a positive profile and the separators 231b of an overhang structure are completed. Further, the hydrophobic silicon oxide films 240 are formed on the surfaces of the insulating layers 231a.

Thereafter, as illustrated in FIGS. 4I and 5I, an organic light-emitting layer 260 and a second electrode 270 as a cathode layer are formed on the first electrodes 220 on the transparent substrate where the insulating layers 231a. and the separators 231b are formed, thereby manufacturing the organic EL display.

In other words, the method for manufacturing an organic EL display in accordance with the second preferred embodiment can greatly reduce a product cost of the organic EL display by simultaneously forming the insulating layers 231a having a positive profile and the separators 231b of an overhang structure with the use of a negative photoresist layer of a single layer instead of a image-reversal photoresist layer of a high price. Further, by forming the hydrophobic silicon oxide films 240 or the like on the surfaces of the insulating layers 231a, it is possible to prevent moisture or an organic solvent remaining in the insulating layers 231a from being discharged to an outside of the insulating layers 231a, i.e., to the pixel.

Furthermore, in accordance with this embodiment, by forming the hydrophobic silicon oxide films 240, moisture can be prevented from penetrating or being adsorbed thereinto from the outside during the manufacturing process of the organic EL display.

While the invention has been shown and described with respect to the preferred embodiments, it will be understood by those skilled in the art that various changes and modification may be made without departing from the scope of the invention as defined in the following claims.

For example, in the first and the second preferred embodiment, the first exposure process is performed by using the photo mask having a single transparent area corresponding to the positive photoresist layer (or the negative photoresist layer employed in the second preferred embodiment) on the third areas (or the first areas employed in the second preferred embodiment), thereby forming the separators of an overhang structure. However, the first exposure process can also be carried out by using a photo mask having a shield area corresponding to the positive photoresist layer (or a negative photoresist layer in the second preferred embodiment) on certain central portions of the third areas (or the first areas in the second preferred embodiment) and a light-transmitting area provided at a peripheral portion of the shield area. Accordingly, as in Reference 2, trenches serving as the separators are formed on the insulating layers crossing the first electrodes.

The organic EL display can be manufactured by performing post processes in accordance with the present invention, which is also included in the scope of the invention. Further, it will be understood by those skilled in the art that various changes and modification of the invention may be made without departing from the scope of the invention as defined in the following claims.

As described above, in accordance with the present invention, a product cost of the organic EL display can be greatly reduced by simultaneously forming the insulating layers and the separators with the use of a positive or a negative photoresist layer of a single layer instead of a image-reversal photoresist layer or a half tone mask of a high price.

Moreover, by forming the hydrophobic silicon oxide films or the like on partial or entire surfaces of the insulating layers and the separators, it is difficult to discharge moisture or an organic solvent remaining in the insulating layers and the separators to the outside by the outgassing. Accordingly, it is possible to solve the drawbacks in which the pixel unit degraded by the moisture or the organic solvent during the driving of the organic EL display causes defects such as dark spots or the like. As a result, the reliability of the organic EL display can be greatly enhanced and, also, a life time thereof can be prolonged.

In addition, since the hydrophobic silicon oxide films are formed the partial or the entire surfaces of the insulating layers and the separators, the moisture can be prevented from penetrating or being adsorbed thereinto from the outside during the manufacturing process of the organic EL display.

What is claimed is:

1. A method for manufacturing an organic electroluminescence (EL) display, comprising the steps of:
(a) forming a plurality of strip-shaped first electrodes on a substrate;
(b) forming a positive photoresist layer on an entire surface of the substrate where the plurality of first electrodes are formed;
(c) patterning the positive photoresist layer to remain a first area of the positive photoresist layer crossing the first electrodes and a second area of the positive photoresist layer between the first electrodes;
(d) performing a first exposure process on a third area of the patterned positive photoresist layer, the third area being crossed the plurality of first electrodes;
(e) performing a first silylation process on the positive photoresist layer exposed by the first exposure step (d);
(f) performing an ashing process on the first to the third areas of the positive photoresist layer with an oxygen plasma; and
(g) performing a hard baking process on the ashed result.

2. The method of claim 1, further comprising, after the hard baking step (g), the steps of: (h) performing a second exposure process on the entire surface of the positive photoresist layer;
(i) performing a second silylation process on the exposed negative photoresist layer by the second exposure step (h); and
(j) processing the silylated positive photoresist layer by the second silylation step (i) with an oxygen plasma.

3. The method of claim 1, further comprising the step of sequentially forming an organic light-emitting layer and a second electrode on the first electrodes after the hard baking step (g).

4. The method of claim 2, further comprising the step of sequentially forming an organic light-emitting layer and a second electrode on the first electrodes after the oxygen plasma processing step (j).

5. The method of claim 1, wherein the first exposure step (d) is performed by using a photo mask having a light-transmitting area corresponding to the third area, the width of the mask being smaller than an upper width of the first area of the patterned positive photoresist layer.

6. The method of claim 5, wherein the photo mask is aligned to make a center of the third area exposed by the first exposure step (d) coincide with that of the patterned positive photoresist layer in the first area.

7. The method of claim 1, wherein the first silylation processing step (e) includes a step of reacting an upper surface of the first-exposed positive photoresist layer with one or more silyl compounds selected from a group including trimethylsilyldiethylamine, N,N-dimethylaminotrimethylsilane, 1,1,3,3-tetramethyldisilane, dimethylsilyldimethylamine, dimethylsilyldiethylamine, hexamethylcyclotrisilazine and bis (N,N-dimethylamino) methylsilane.

8. The method of claim 2, wherein the second silylation processing step (i) includes a step of reacting the entire surface of the second-exposed positive photoresist layer with one or more silyl compounds selected from a group including trimethylsilyldiethylamine, N,N-dimethylaminotrimethylsilane, 1,1,3,3-tetramethyldisilane, dimethylsilyldimethylamine, dimethylsilyldiethylamine, hexamethylcyclotrisilazine and bis (N,N-dimethylamino) methylsilane.

9. A method for manufacturing an organic electroluminescence (EL) display, comprising the steps of:
(a) forming a plurality of strip-shaped first electrodes on a substrate;
(b) forming a negative photoresist layer on an entire surface of the substrate where the plurality of first electrodes are formed;
(c) performing a first exposure process on a first area of the negative photoresist layer crossing the first electrodes;
(d) performing a first baking process on the exposed negative photoresist layer by the first exposure step (c);
(e) developing a remainder of the negative photoresist layer unexposed by the first exposure step (c) to leave a designated thickness of the negative photoresist layer;
(f) performing a second exposure process on areas of the negative photoresist layer excepting the second area crossing the first electrodes and the third area between the first electrodes;
(g) performing a second baking process on the exposed negative photoresist layer by the second exposure step (f);
(h) performing a third exposure process on the entire surface of the negative photoresist layer;
(i) performing a first silylation process on the exposed negative photoresist layer by the third exposure step (h);
(j) processing the entire surface of the negative photoresist layer with an oxygen plasma; and
(k) performing a hard baking process on the ashed result.

10. The method of claim 9, further comprising, after the hard baking step (k), the steps of:
(l) performing a fourth exposure process on the negative photoresist layer;
(m) performing a second silylation process on the fourth-exposed negative photoresist layer; and
(n) processing the silylated photoresist layer by the second silylation step (m) with an oxygen plasma.

11. The method of claim 9, further comprising the step of sequentially forming an organic light-emitting layer and a second electrode on the first electrodes after the hard baking step (k).

12. The method of claim 10, further comprising the step of sequentially forming an organic light-emitting layer and a second electrode on the first electrodes after the oxygen plasma processing step (n).

13. The method of claim 9, wherein the second exposure step (f) is performed by using a lattice patterned photo mask having shield areas corresponding to the second area and the third area, a width of the second area being larger than that of the first area.

14. The method of claim 13, wherein the photo mask is aligned such that a center of the second area shaded in the second exposure step (f) coincides with that of the first area of the negative photoresist layer.

15. The method of claim 9, wherein the first silylation step (i) includes a step of reacting a surface of the exposed positive photoresist layer by the third exposure step (h) with one or more silyl compounds selected from a group including trimethylsilyldiethylamine, N,N-dimethylaminotrimethylsilane, 1,1,3,3-tetramethyldisilane, dimethylsilyldimethylamine, dimethylsilyldiethylamine, hexamethylcyclotrisilazine and bis (N,N-dimethylamino) methylsilane.

16. The method of claim 10, wherein the second silylation step (m) includes a step of reacting a surface of the exposed positive photoresist layer by the fourth exposure step (l) with one or more silyl compounds selected from a group including trimethylsilyldiethylamine, N,N-dimethylaminotrimethylsilane, 1,1,3,3-tetramethyldisilane, dimethylsilyldimethylamine, dimethylsilyldiethylamine, hexamethylcyclotrisilazine and bis (N,N-dimethylamino) methylsilane.
